(19) United States
(12) Patent Application Publication
(10) Pub. No.: US 2025/0004519 A1
(43) Pub. Date: Jan. 2, 2025

(54) APPARATUS, SYSTEM AND METHOD OF PROVIDING A POWERED SMART FURNITURE UNIT

(71) Applicant: JABIL INC., St. Petersburg, FL (US)

(72) Inventors: Gerald DeGraaf, St. Petersburg, FL (US); Stephen A. McSoley, St. Petersburg, FL (US)

(21) Appl. No.: 18/748,931

(22) Filed: Jun. 20, 2024

Related U.S. Application Data
(63) Continuation-in-part of application No. 18/110,640, filed on Feb. 16, 2023.
Application No. 18/110,640 is a continuation of application No. 17/406,601, filed on Aug. 19, 2021, now Pat. No. 11,609,620.
Application No. 17/406,601 is a continuation of application No. 15/464,176, filed on Mar. 20, 2017, now Pat. No. 11,121,555.
(60) Provisional application No. 63/522,283, filed on Jun. 21, 2023.
(60) Provisional application No. 63/568,222, filed on Mar. 21, 2024.

(51) Int. Cl. G06F 1/26; H02J 3/38; H02J 4/00; H02J 7/02; H02J 7/34; H02J 50/00; H02S 40/32; H02S 40/34; H02S 40/38; H05K 5/00

(52) U.S. Cl. CPC G06F 1/26; G06F 1/263; H02J 3/38; H02J 4/00; H02J 7/34; H02J 50/001; H02S 40/32; H02S 40/34; H02S 40/38; H05K 5/0017; H02J 7/02

(57) ABSTRACT

An apparatus, system and method for a powered smart furniture unit, such as a smart desk chair. Included are: a power unit; a control box unit that receives power from and is communicative with the power unit, and comprises a power output suitable to output power to features of the smart desk chair; a plurality of strain gauges affixed to portions of the smart desk chair and receiving power from the power supply; a plurality of comfort outputs affixed to portions of the smart desk chair and receiving power from the power supply; and an application wirelessly associated with the plurality of strain gauges and the plurality of comfort outputs capable of communicating wirelessly with the plurality of strain gauges and the plurality of comfort outputs.

### CROSS-REFERENCE TO RELATED APPLICATIONS

This application claims the benefit of U.S. Provisional Patent Application No. 63/522,283, filed Jun. 21, 2023, entitled: “Apparatus, System and Method of Providing a Powered Smart Chair in an Office Environment” and U.S. Provisional Patent Application No. 63/568,222, filed Mar. 21, 2024, entitled: “Apparatus, System and Method of Providing a Powered Smart Furniture Unit.” This application is also a Continuation-In-Part Application of Ser. No. 18/110,640, filed Feb. 16, 2023, entitled: “Apparatus, System and Method of Providing Power in an Office Environment,” which is a Continuation of U.S. patent application Ser. No. 17/406,601, filed Aug. 19, 2021, entitled: “Apparatus, System and Method of Providing Power in an Office Environment,” which claims priority to U.S. patent application Ser. No. 15/464,176, filed Mar. 20, 2017, entitled: “Apparatus, System and Method of Providing Power in an Office Environment,” which claims priority to International Application No. PCT/US2018/023236, filed Mar. 20, 2018, entitled: “Apparatus, System and Method of Providing Power in an Office Environment.” All applications listed herein are incorporated by reference in their entireties.

### BACKGROUND

### Field of the Disclosure

The present disclosure relates to smart furniture, and, more specifically, to an apparatus, system and method of providing a powered smart furniture unit.

### Description of the Background

The work environment is often sedentary. A major disadvantage of this is that it adversely affects employee health and wellbeing. These adverse effects may be minor, such as aches and pains in the back, hips, or legs, or weight gain and muscular atrophy; or may be significant, such as developing serious medical conditions like deep vein thrombosis or diabetes. In light of these adverse effects, employees should be encouraged to stay active, or at least move about, throughout the working day.

More particularly, in a typical office environment, a worker is provided with at least a desk and a chair. The chair is generally not employee-specific; rather, it is a generic chair, and is typically the same or similar size and shape for all employees. The typical chair does not have electronic controls or conveniences. As such, the typical chair is not capable of “helping” a user's comfort, and hence the user's productivity, which could be helped by having the user maintain a good posture, by cooling or heating the user, and so on, is instead hindered.

Further, it is frequent in current office embodiments that hoteling concepts are employed, wherein employees use non-exclusive office locations, i.e., the aforementioned chair, and/or other office elements, are shared between several employees who use that office space at different times. These hoteling environments in particular, and most office environments in general, may thus provide standardized chairs, thereby precluding individualized improvements in environmental conditions or ergonomics of use to increase the productivity of whoever is the current user.

Of course, it will be appreciated that remaining sedentary, due in part to the use of furniture, is not unique to office chairs. For example, the issues stemming from lying still for ling periods of time may be even more severe for users in hospital beds or wheelchairs, by way of non-limiting example.

Thus, the need exists for a chair, bed, or similar type of furniture-type unit that provides improved ergonomics, user interactions, and/or environmental conditions so as to increase user health, well-being and productivity.

### SUMMARY

An apparatus, system and method for providing a powered smart furniture unit, such as a smart desk chair. Included may be: a power supply at least partially integrated with a chair frame in embodiments wherein the furniture unit is a smart desk chair; and a control box unit associated with the chair frame and which receives power from and is communicative with the power unit, and comprises a power output suitable to output power to features on the chair frame. The features may include: a plurality of strain gauges affixed to portions of the smart desk chair and receiving power from the power supply; and a plurality of comfort and well-being outputs affixed to portions of the smart desk chair and receiving power from the power supply. Also included in the apparatus, system and method may be an application wirelessly associated with the plurality of strain gauges and the plurality of comfort and well-being outputs capable of providing user and automated control of, and information related to, use of the smart desk chair and actuation of the comfort and well-being outputs by communicating wirelessly with the plurality of strain gauges and the plurality of comfort and well-being outputs.

Thus, the disclosed embodiments provide an apparatus, system, and method for providing a powered smart furniture unit, such as a desk chair or a hospital bed, to provide improved ergonomics and environmental conditions so as to increase health, well-being and productivity.

### BRIEF DESCRIPTION OF THE FIGURES

Referring now to the figures incorporated herein, shown are non-limiting embodiments of the present disclosure, wherein like numerals represent like elements, and wherein:

FIG. 1 is a diagram of power provision in an office environment;

FIG. 2 is a diagram of a control box unit for managing power provision;

FIG. 3 is a diagram of powered office furniture;

FIG. 4 illustrates aspects of the embodiments;

FIG. 5 illustrates aspects of the embodiments;

FIGS. 6A, 6B, 6C and 6D illustrate aspects of the embodiments;

FIG. 7 illustrates aspects of the embodiments;

FIG. 8 illustrates aspects of the embodiments;

FIG. 9 illustrates aspects of the embodiments;

FIG. 10 illustrates aspects of the embodiments;

FIG. 11 illustrates aspects of the embodiments;

FIG. 12 illustrates aspects of the embodiments;

FIG. 13 illustrates aspects of the embodiments;

FIGS. 14A and 14B illustrate aspects of the embodiments;

FIG. 15 is a diagram of a computing system; and

FIG. 16 illustrates aspects of the embodiments.

### DETAILED DESCRIPTION

The figures and descriptions provided herein may have been simplified to illustrate aspects that are relevant for a clear understanding of the herein described apparatuses, systems, and methods, while eliminating, for the purpose of clarity, other aspects that may be found in typical similar devices, systems, and methods. Those of ordinary skill may thus recognize that other elements and/or operations may be desirable and/or necessary to implement the devices, systems, and methods described herein. But because such elements and operations are known in the art, and because they do not facilitate a better understanding of the present disclosure, for the sake of brevity a discussion of such elements and operations may not be provided herein. However, the present disclosure is deemed to nevertheless include all such elements, variations, and modifications to the described aspects that would be known to those of ordinary skill in the art.

Exemplary embodiments are provided throughout so that this disclosure is sufficiently thorough and fully conveys the scope of the disclosed embodiments to those who are skilled in the art. Numerous specific details are set forth, such as examples of specific components, devices, and methods, to provide a thorough understanding of embodiments of the present disclosure. Nevertheless, it will be apparent to those skilled in the art that certain specific disclosed details need not be employed, and that exemplary embodiments may be embodied in different forms. As such, the exemplary embodiments should not be construed to limit the scope of the disclosure. As referenced above, in some exemplary embodiments, well-known processes, well-known device structures, and well-known technologies may not be described in detail.

The terminology used herein is for the purpose of describing particular exemplary embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The steps, processes, and operations described herein are not to be construed as necessarily requiring their respective performance in the particular order discussed or illustrated, unless specifically identified as a preferred or required order of performance. It is also to be understood that additional or alternative steps may be employed, in place of or in conjunction with the disclosed aspects.

When an element or layer is referred to as being “on”, “engaged to”, “connected to” or “coupled to” another element or layer, it may be directly on, engaged, connected or coupled to the other element or layer, or intervening elements or layers may be present, unless clearly indicated otherwise. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). Further, as used herein the term “and/or” includes any and all combinations of one or more of the associated listed items.

Yet further, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another element, component, region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the exemplary embodiments.

Certain of the embodiments provide a smart movable or stationary furniture unit. The unit may be a chair, such as a desk chair, a bed, such as a hospital bed, and may be stationary or mobile, such as a wheelchair. The unit may be any structure on which a person may sit, lie, or rest upon, and from which it would be advantageous to: draw data from; create a profile in relation to; derive conclusions from any profile created in relation to; and/or enhance the ergonomics or usability of, such as based on user preferences.

These data, profiles, conclusion, adjustments, and the like may stem from sensors associated with the unit. These same data, profiles, conclusions, adjustments and the like may be generated locally and effectuated locally, such as via a phone app, or may be conveyed remotely, such as via a network, for remote processing and decision making, which may then be conveyed back across the network.

Further, the unit may be connected, such as via one or more network connective methodologies, to the internet of things (IoT), such as to provide notifications to and/or access in relation to, the needs of the unit, such as for power, an upload or download connection, a user request, or the like. The unit may have on-board power, such as a battery, may plug in, or may include one or more ambient energy collector(s) to suitably receive, for example, heat energy, solar energy, light energy, kinetic energy or RF energy or the like.

In alternative embodiments, a power unit and/or one or more control boxes/units may be co-located near, but not on, the furniture unit. The communication of power and/or the exchange of sensor and/or control data may, in such cases, occur via wire or wirelessly.

The control box and the power unit may be co-extensive or connected to each other, and may be connected to other control boxes and/or power units via wires, wirelessly, and in some cases, by both. These and the aforementioned connections may also include a network connection, such as to provide for IoT interoperability, data accumulation, and control, by way of non-limiting example. This IoT presence, as discussed here and above and which my be upon or off the furniture unit, allows for real time reporting of status, station availability, power availability, power needs, user data, user profile, and/or grouped units, active units, or changes in user between units connected within the network.

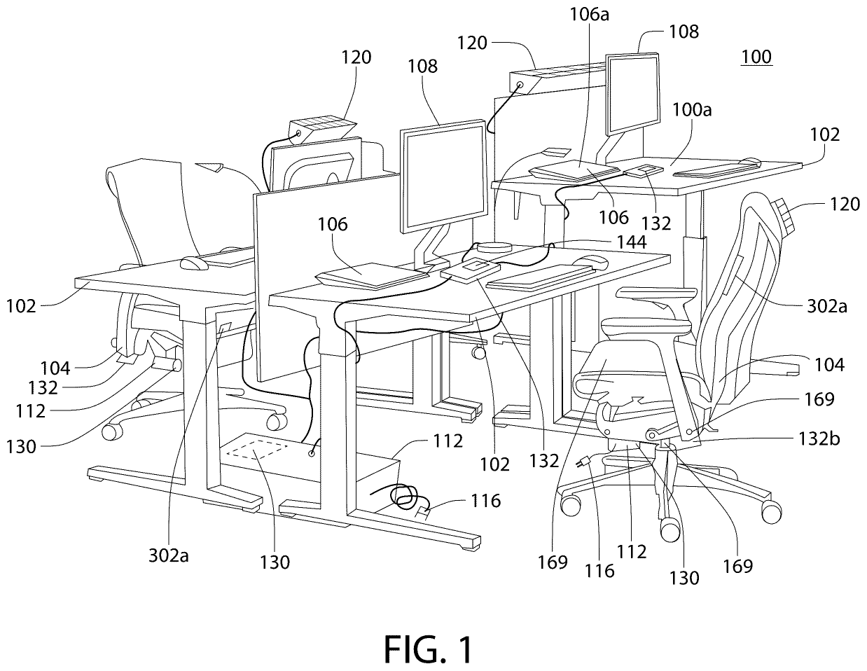

FIG. 1 illustrates an embodiment of an office 100 having exemplary disclosed aspects. In the illustration of office 100, multiple desks 102, chairs 104, and computers 106 may be provided. Among the computers provided may be one or more laptop computers 106a which operate using DC power, unlike desktop computers or lights 110, which, as will be apparent to the skilled artisan, use AC power. Moreover, it may be noted that the displays 108 illustratively associated with laptops or desktops may use AC or DC power, dependent on the type and make of the display.

Further illustrated in FIG. 1 is a power unit 112. Of note, the power unit 112 may have one or more temporary or permanent power inputs 116, such as: for recovery of power; a battery; or supplemental power. That is, the power unit 112 may be plugged and unplugged intermittently from available wall or floor power sockets, such as to avoid the permanent presence of one or more cords inconveniently within a walking path around the area 100, and such as to recharge a battery on the furniture unit 102, 104.

The power unit 112 may have connectively associated therewith, such as via the connective cabling or wirelessly, one or more ambient energy collectors 120 that may provide power for power. Such ambient energy collectors 120 may include, by way of non-limiting example, solar collectors, and may be placed physically in association with the furniture units at points best suited to collect the desired type of energy, such as solar energy, heat energy, light energy, or kinetic energy.

Additionally associated with furniture unit 104 may be a network connectivity module 130, such as wi-fi, Bluetooth, near field communication (NFC), or the like. Such a network connectivity module 130 may additionally include wired connectivity. The power unit 112 may also provide the power necessary to operate one or more components of the network connectivity module 130. The network connectivity module 130 may additionally or alternatively be associated with control box 132, as discussed below.

Network connectivity 130 may, in conjunction with or in addition to control unit 132, allow for actuation of one or more features 169 on the furniture unit 104. Such features may include, for example, heating, cooling, reclining, alerts, raising, lowering, lumbar support, and so on. The actuation of such features may be discerned locally or remotely, and may be based, at least in part, on data provided by sensors 302.

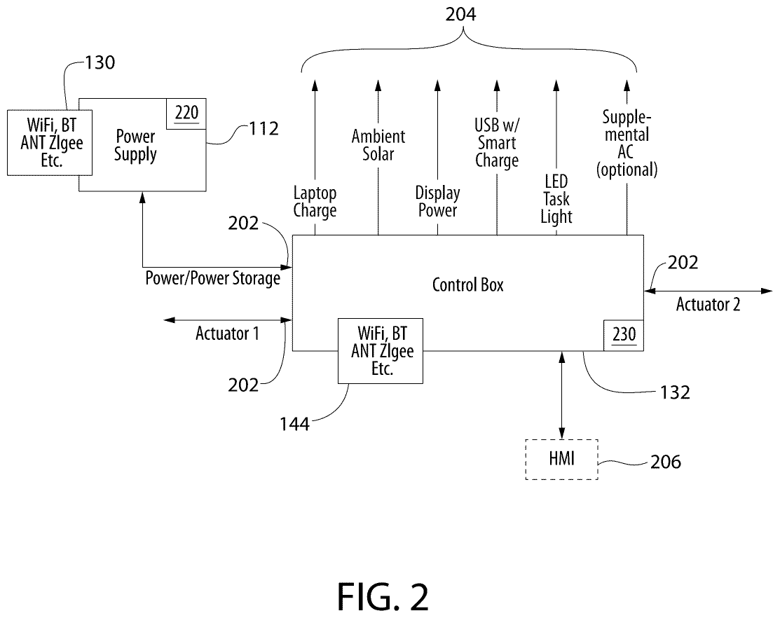

FIG. 2 illustrates the plurality of inputs and outputs 202, 204, that may be provided on each control box unit 132 to enable the interactivity discussed throughout. As illustrated in FIG. 2, each control box unit 132 may additionally have associated therewith a human machine interface (HMI) 206. The HMI 206 may allow for interaction by a user with the control box 132, such as to allow for setting up of particular features operated from the control box unit 132, setting up a power supply unit 112, setting up wireless or wired network connectivity module 144 by the control box unit 132, and the like. The HMI may be partially resident on a user's phone or laptop, such as in the form of an app, and partially on the furniture unit 104.

As is further illustrated in FIG. 2, the power unit 112 may include one or more batteries 220. The batteries 220 may, as referenced above, include or accumulate a stored charge for a given timeframe (such as one workstation per day, which may be a charge of approximately 2 kWhrs).

As further illustrated, the power unit 112 may include capabilities to deliver power of one or more types (for example AC, DC, sine wave, or square wave) through one or more outputs. Moreover, secondary power, such as recharging power for battery, may be received at one or more inputs 116, as discussed herein above. Yet further, the power unit 112 may include one or more software modules acting as power control modules 230, such as to manage the accumulation and delivery of power, including to various sensors and/or features of the furniture unit 104.

Yet further, certain of the disclosed aspects may allow for IoT intercommunication as between the furniture unit 104, office devices, work stations, power supplies, and so on, and further may allow for personalization and individualization of the furniture unit, through use of IoT.

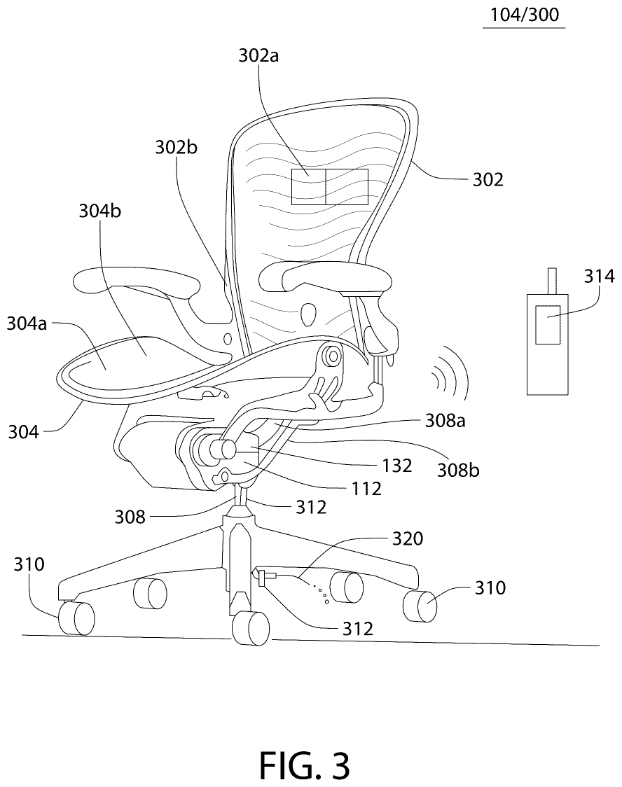

FIG. 3 illustrates a chair 104/300. The chair 300 may be employed along with or discretely from the herein described embodiments. A chair 300 according to certain of the embodiments may include onboard aspects, such as low voltage enhancements, to improve productivity of the user. Moreover, the chair may include enabling electronics, network productivity, power management capability, and data transmission capability, as well as a series of actuatable features such as heating/cooling, buzzers, speakers, height, lumbar, seat back, or seat adjustments, such as using a data feed to or from an onboard (or off-board) control box unit 132 as discussed herein above, or via wire or wireless communication with an off-board control box unit 132.

More particularly, chair 300 may include a chair back 302, a chair seat 304, a rigid connective structure 308 between the seat 304 or back 302 and the wheels, and a plurality of wheels 310. Moreover, the chair 300 may include one or more electrical conduits 312, such as may rotate or roll and such as may extend downwardly from a hub 310a at which the plurality of wheels 310 are connectively associated. The electrical conduit 312 may carry one or more wires 320, such as to supply power to, and transmit/receive data to or from, aspects of the chair 300.

As referenced above, the chair/bed 300 may include the one or more aforementioned control box units 132, such as may be onboard and may communicate by wire or wirelessly with off-board aspects. For example, the control box unit 132 may control power supplied to aspects of the chair 300. This power may be supplied from onboard the chair 300, such as via battery, from external AC power to the chair 300, or from any other power unit 112 as discussed herein above. Further, the control box unit 132 (and/or power unit 112) may include AC to DC conversion capabilities as necessary, and the power unit 112 may be on the chair 300 and may thus include the ability to store and/or charge power onboard the chair 300.

For example, the power unit 112, such as when onboard the chair 300, may include inductive recharging and power maintenance, kinetic recharging and power maintenance, and/or ambient recharging and power maintenance, by way of non-limiting example, and may receive data related to the foregoing from the control box unit 132. The control box unit 132 may further receive data, such as from aspects of the chair 300, and may send this data to one or more apps 314 or applications to: receive feedback from the user of the chair 300, such as for chair adjustments; and/or to provide feedback to the user, such as how to better, more ergonomically, more productively, or otherwise more helpfully use the chair; and/or to provide the user with alerts, etc., using, including by actuating features of the chair; and/or to actuate features of the chair based on user instruction or automatically.

As such, the data communicated via the control box unit 132 may include, by way of non-limiting example, storage of preset values, such as locations of aspects of the chair, sensing of locations of aspects of the chair, sensing of movement, heart, respiration, indications of user-comfortable temperature, adequacy of light per user, or the like. The control box unit 132 of the chair 300 may transmit/receive this data, such as to/from one or more networks via Wi-Fi, wire, Bluetooth, NFC or the like. Of note, although these control box unit aspects may be described with respect to the example of FIG. 3 as onboard the chair 300, the skilled artisan will appreciate in light of the present discussion that the chair 300 may, additionally or alternatively, be connectively associated, such as via wire or wirelessly, with one or more off-board control units to perform the functions discussed herein throughout.

The back 302 of the chair may include a sensor grid, such as a 3×3 or 2×2 grid of sensors, by way of example, which may sense, for example, user presence, user position, and environmental factors. Moreover, the sensors 302a may assess pressure and/or temperature. Yet further, either based on sensor feedback, user presets, or the like, the seatback 302 may include actuatable features 169/302b, such as lumbar support pressure actuators, and/or one or more lumbar, seat or seatback warmer or coolers, by way of non-limiting example.

The seat 304 and/or any provided armrest of the chair may additionally include sensor grids, such as 3×3 sensors. These sensors 304a may again sense user position, or environmental conditions, by way of example. Moreover, the seat and/or armrest may include actuatable features 304b, such as variable padding adjustments, warming or cooling, by way of example.

The rigid structure 308 may include electronic height adjustment, electronic seatback adjustment, or the like, and may include capability to automatically set the foregoing per user preferred presets and sensors 308a to sense the foregoing. The rigid structure 308 may additionally include actuatable features 308b, such as an electronic tensioner, by way of non-limiting example.

As discussed above, various sensing and/or automatic adjustments of office furniture may be provided in accordance with certain of disclosed embodiments. Such sensing and/or adjustments may include weight and weight distribution, heart rate, respiration rate, estimated stress level based on biometric feedback, seat height, seatback or seat tension, extent of reclined position, or the like.

By way of more specific example, strain gauges, or a strain gauge array, may be bonded to the chair in strategic locations to act as sensors 302a, such as to discern the weight and/or position and/or posture of the chair's occupant. Strain gauge locations may be determined, for example, based on chair material flex points and/or due to likely varying positions of the user. Strain gauges may be placed in or on the chair wheels, the chair support pedestal, the chair seat, and the chair back, the chair headrest, and/or the chair arm rests, for example.

Strain gauge bonding may take place on metal, fabric and plastic areas. Gauges may be bonded to the materials using a adhesive, tape, micro-tape, Velcro, stitching, interweaving with, and so on. Strain Gauges may be uni-axial and/or tri-axial, wherein the tri-axial gauges are sensitive to strain in three different axes. The chair may include microprocessing capabilities, and these may be wired to the strain gauges or may wirelessly communicate with the strain gauges and with a controller, such as may comprise an app or application on a mobile device, laptop, or dedicated control pod such as might be placed on a desktop. Conversely, the sensors may communicate, via wire or wirelessly, with an off-chair processor.

Strain gauges are typically copper nickel foil structures that change in electrical resistance when they are mechanically distorted. Tri-axial strain gauges may be sensitive to strain in three axis, i.e., at 0, 45 and 90 degrees. Maximum and minimum principal strains and strain directions may be calculated using the data from the 3 axes as follows:

### Maximum Principal Strain

$${ε}_{P} = \frac{{ε}_{1} + {ε}_{3}}{2} + \frac{1}{\sqrt{2}} \sqrt{{( {ε}_{1} - {ε}_{2} )}^{2} + {( {ε}_{2} - {ε}_{3} )}^{2}}$$

### Minimum Principal Strain

$${ε}_{Q} = \frac{{ε}_{1} + {ε}_{3}}{2} - \frac{1}{\sqrt{2}} \sqrt{{( {ε}_{1} - {ε}_{2} )}^{2} + {( {ε}_{2} - {ε}_{3} )}^{2}}$$

### Strain Direction Calculator

$${ϕ}_{P , Q} = θ = \frac{1}{2} {tan}^{- 1} ( \frac{2 * {ε}_{2} - {ε}_{1} - {ε}_{3}}{{ε}_{1} - {ε}_{3}} )$$

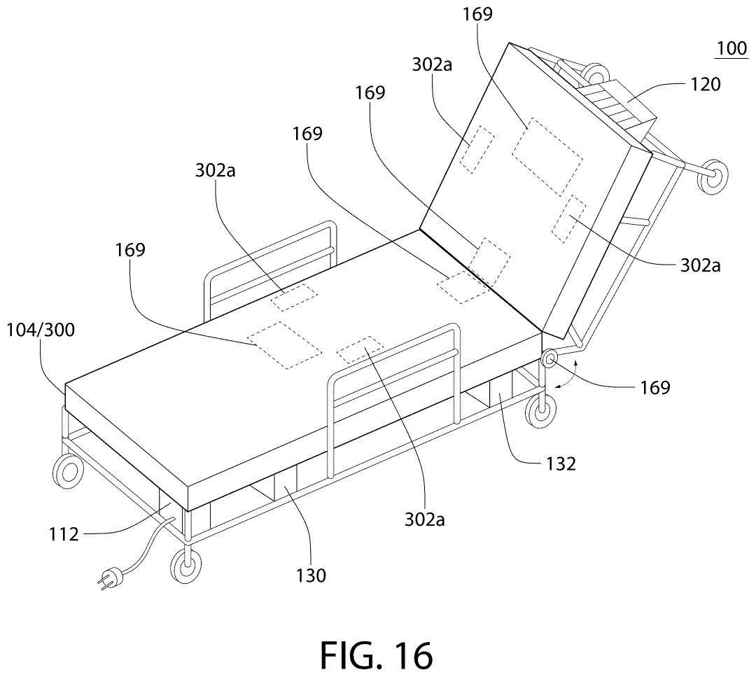

FIG. 16 illustrates an embodiment akin to the aspects discussed above in relation to a chair, but with a different furniture unit 104. More particularly, the furniture unit illustrated in this exemplary embodiment is a hospital bed 104 in area 100. Needless to say, the sensors/strain gauges 302a may operate as discussed throughout, such as to actuate features 169 by communicating with control unit 132 to receive actuation outputs, such as may use power from power unit 112, even when the furniture unit varies, such as wherein the unit is a bed. Further, it will be appreciated that the sensors 302a and actuatable features 169 may vary in position according to the type of furniture unit 104/300. For example, the sensors 302a may be placed in particular locations in a mattress and/or on a bed frame in a manner corresponding to the chair, chair seat, chair back, and chair frame as discussed throughout.

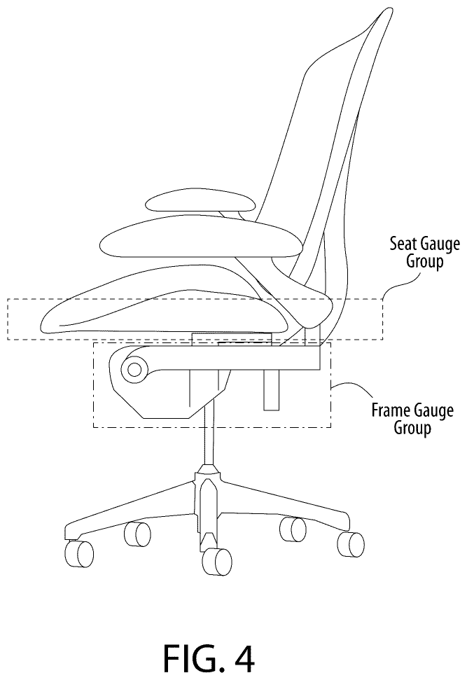

FIG. 4 illustrates two gauge group/sensor areas 302a, such as may be treated separately for processing purposes. The first gauge group is on the chair frame, and the second strain gauge group is on the chair seat.

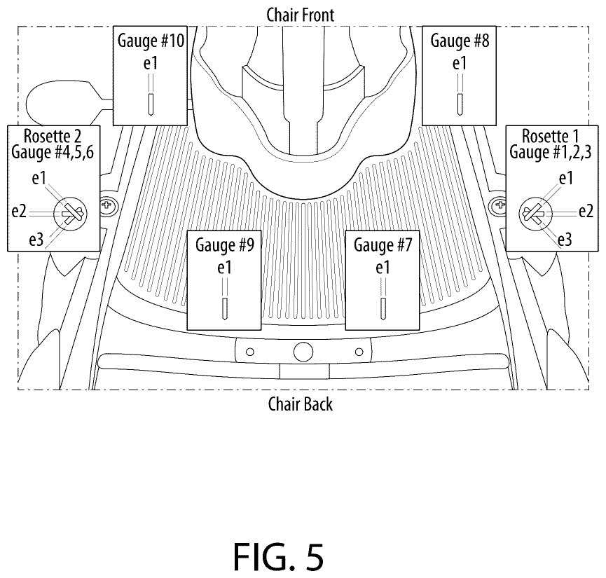

FIG. 5 illustrates the chair frame gauge group with greater particularity. As illustrated, both single axis (sensors 7, 8, 9, 10) and tri-axis (sensors 1-2-3, and 4-5-6) sensors 302a may be used. Each sensor and/or sensor group 302a may be oriented, in conjunction with the orientation and positional of aspects of the chair frame (i.e., chair front and chair back, as shown), so as to indicate desired quantities, such as weight, position, or posture, when data from the individual sensors and sensor groups is processed.

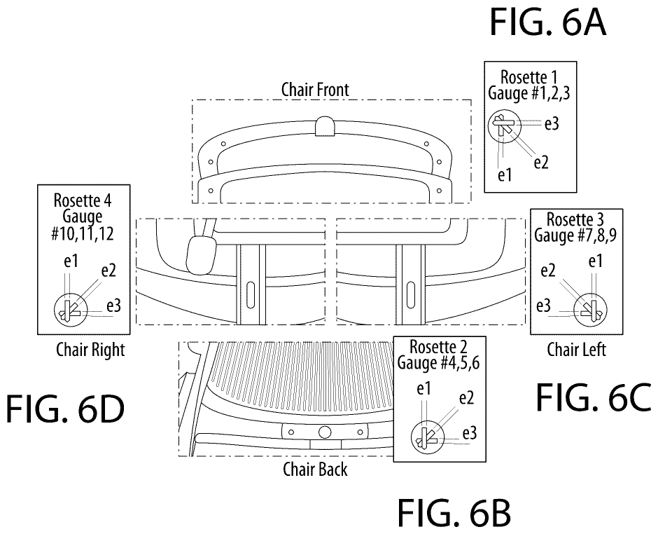

Likewise, FIGS. 6A-D illustrate the seat gauge group 302a for processing purposes. Again, both single axis and tri-axis (sensors 1-2-3, 4-5-6, 7-8-9, and 10-11-12) sensors 302a may be used. Each sensor and/or sensor group 302a may be oriented, in conjunction with the orientation and position of aspects of the chair frame (i.e., chair front, back, left and right, as shown), so as to indicate desired quantities, such as weight, position, or posture, when data from the individual sensors and sensor group is processed.

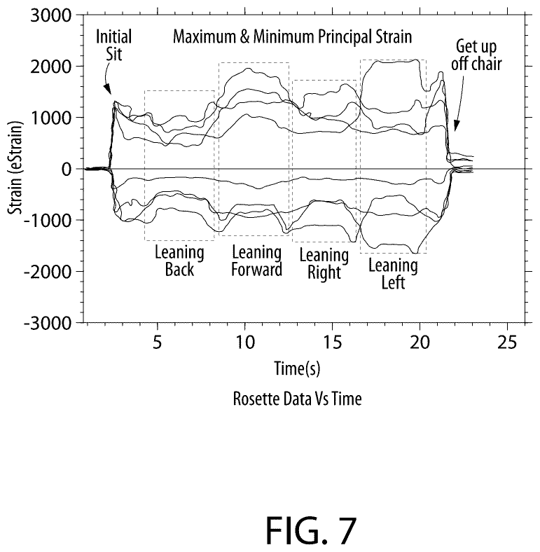

FIG. 7 is a graph showing the response of 4 strain gauges under the seat perimeter frame when a person sits on the chair. The data indicates that the person first leans backwards, then forward, then to the right, then to the left, and then gets up.

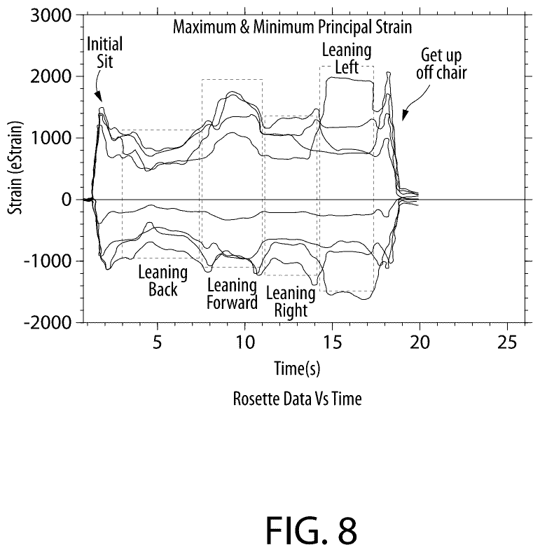

FIG. 8 illustrates a second person following the same sequence of positioning as the person corresponded to the data of FIG. 7. However, the second person corresponded to the data of FIG. 8 is of a different size, a different weight, and has different body proportions than the person corresponded to the data of FIG. 7.

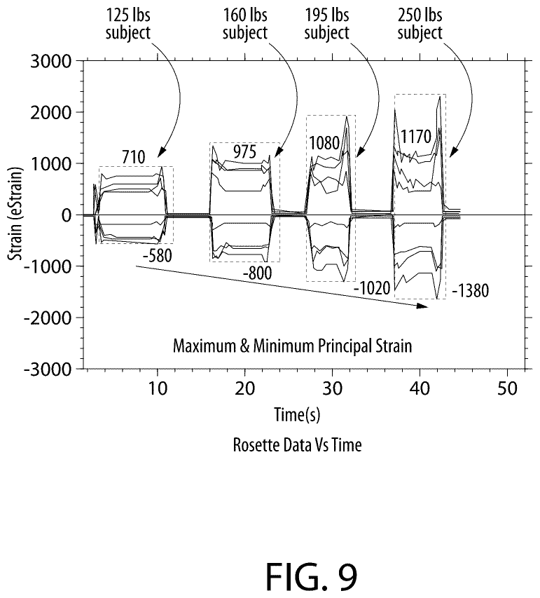

More particularly, FIG. 9 shows four different subjects (of weights 125 lbs.-160 lbs.-195 lbs.-250 Lbs) sitting on a seat having the strain gauge groups shown above under the seat perimeter frame. The data separation between persons of different weights is thus very clearly available in the compressive strain data.

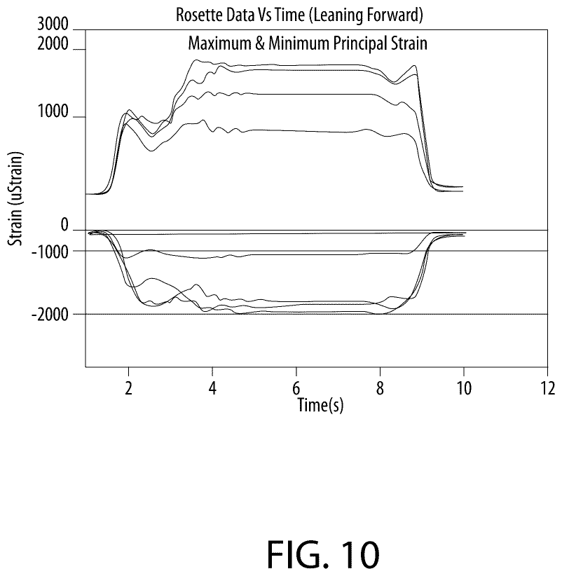

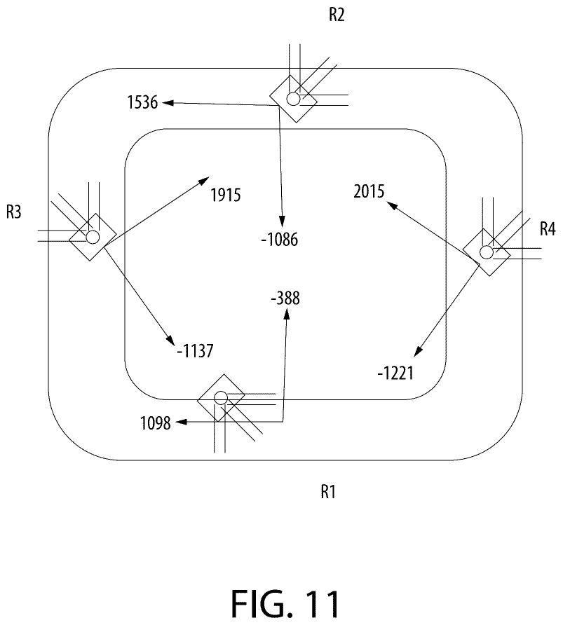

FIGS. 10 and 11 illustrate the data for, and the sensor results and direction vectors for (respectively), a person leaning forward on the chair. Leaning forward results in strain increasing on the backside of the seat perimeter frame, as shown. A normal centered sit from this person would measure about 1000 micro strains. That is, FIG. 11 shows the calculated maximum and minimum principal strains and their directions from the data of FIG. 10.

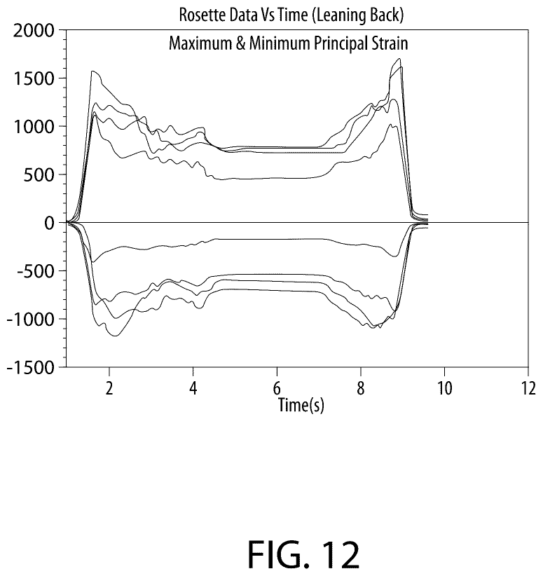

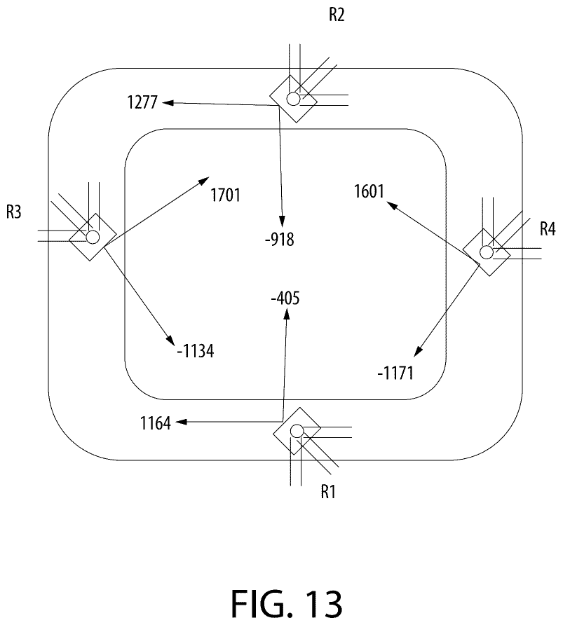

Similarly, FIG. 12 shows data indicative of a user leaning back in the chair, which results in strain decreasing on most of the strain gauges. FIG. 13 illustrates the calculated maximum and minimum principal strains and their directions from the data of FIG. 12.

A comparison of the calculated maximum and minimum principal strains and corresponding direction vectors as between FIGS. 11 and 13 make clear the differences in the processed data between a front lean and a back lean. That is, the data from the strain gauges is clearly suitable to indicate when a person leans one way or another in the chair.

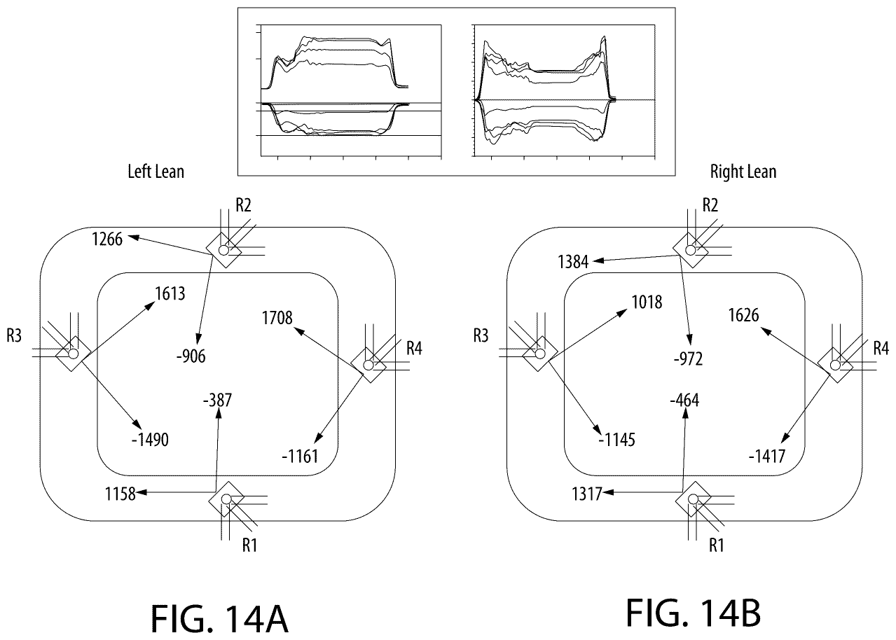

Likewise, FIG. 14 illustrates a comparison of both sensor data output, and processed maximum and minimum principal strains and strain directions, for a left chair lean and a right chair lean. It should also be noted that, in some cases and based on the position of the user in the chair and the position of the strain gauge along the seat of the chair, the strain vector direction may actually oppose the direction of the lean.

In accordance with the foregoing, the office furniture experience may be personalized. Personalization of the office furniture experience further contributes to improvement of the increasingly common hotel environments in an office setting. That is, employees frequently rotate and share spaces in today's business environment, and thereby IoT-connected office furniture, such as a chair, will improve usage of space and individual user comforts, such as by employing preset values and user feedback. Such enhancements to user comfort may also include user interaction made from the office furniture, such as may be sensed by the control box unit. Such sensed interactions may include interactions with a mobile device, laptop, or the like, and may include other factors relatedly stored together with the recorded interaction, such as environmental conditions, light levels, ambient temperature, and the like. These other factors may then be adjusted based on each individual user, such as to facilitate typical interactions by that user.

Yet further, user productivity and overall health may be improved in the embodiments. For example, in a manner akin to current health apps/fitness trackers, the disclosed chair and/or an associated app may instruct the user to sit in a different position, improve the user's posture, or to get up and move at appropriate times, such as to improve the user's health and mental state. Additionally, the app may adjust the chair environmentally, such as via heating or cooling, and likewise the user may request certain functions, i.e., if the user has injured her lower back, she may request that the chair provide lumbar heating, but because the office is already warm, she may not want heating from the remainder of the chair, or she may want cooling from the other portions of the chair.

Moreover, each user may have a stored profile, which may include needed or desired health features/maladies of the user. Likewise, the profile may include the user's likes and dislikes. These likes and dislikes may include heating and cooling, chair firmness, lumbar support, and so on.

Thereby, the furniture unit's sensor output may be compared to the user's profile, and the unit's features may be adjusted accordingly. For example, the chair cooling may be actuated because the air temperature is currently sensed as 78 degrees, and the use prefers a range of 68-70 degrees. Similarly, the lumbar support may be extended/firmed for a use having a profile indicating a lower back problem. Yet further, a user having a profile indicating a history of circulatory problems may receive alert sounds, buzzing, phone alerts, and so on to stimulate the user to move when he/she has been sensed as stationary for an extended period of time.

That is, based on sensor output, the unit may, for example, move the user, or alert the user to move. In some contexts, such as wherein the unit is a hospital bed, the sensors may also indicate when a user has moved or made an adjustment, or, such as based on comparison to known profiled sensor data of known situations for the purpose of pattern recognition, when the foregoing and/or other actions have occurred. For example, sensor data may indicate that a patient is eating, that a nurse has moved or rolled a patient, that a patient has sat up or gotten out of bed, and so on, based on comparison to previously recognized patterns in sensor data used to create a data profile indicative of such actions.

This profiled sensor data may, by way of example, be generated based on sensor data across many units as distinct from, or in addition to, training data. For example, an artificial intelligence (AI) engine may receive data and data circumstances, perform pattern recognition, and may discern therefrom what circumstances certain data profiles correspond to, i.e., sitting, eating, rolling, being rolled, etc.

By way of example, the AI engine may recognize patterns in generated sensor data, and may use this data to tell actors and users of furniture units what to do. For example, a chair may tell a user that, if she doesn't move her foot from under her in the next 2 minutes, her foot may fall asleep; or a bed may tell a nurse or doctor that a patient should be turned in the next 3 hours, or bed sores may develop. Relatedly, whether the recommended action is taken may also be tracked by the AI engine using the sensors, as may be the outcome when the action is taken as suggested, and when it is not.

Thus, the embodiments may be used to both suggest needed action, such as patient care, and/or to keep track that recommended and/or prescribed care has occurred. Further, it will be understood that reminders may be provided at predetermined intervals, and/or alerts may not be cleared and may continue to repeat, until the sensors disclosed indicate to the satisfaction of the AI engine that the indicated and/or prescribed action has been performed.

In light of the above, the disclosed furniture unit may provide a service not available in the prior art. For example, nursing homes may be able to advertise, using the disclosed embodiments, that their beds demand themselves patient care, and their beds cannot be silenced until the requisite care has occurred.

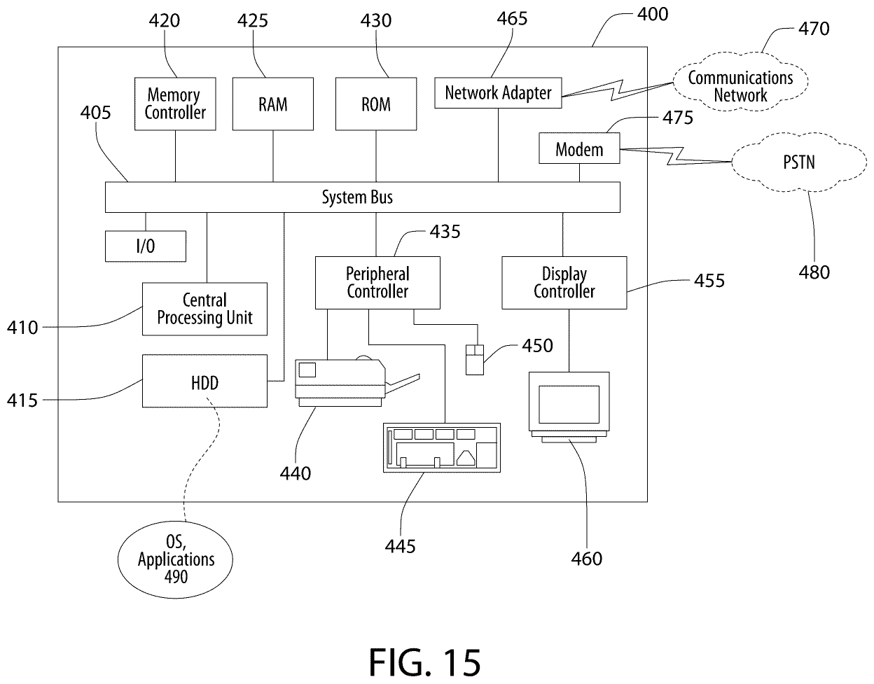

FIG. 15 depicts an exemplary computing system 400 for use in association with a control box unit 132 and/or a power unit 112, for example. Computing system 400 is capable of executing software, such as an operating system (OS) and one or more computing applications 490. The operation of exemplary computing system 400 is controlled primarily by computer readable instructions, such as instructions stored in a computer readable storage medium, such as hard disk drive (HDD) 415, optical disk (not shown) such as a CD or DVD, solid state drive (not shown) such as a USB “thumb drive,” or the like. Such instructions may be executed within central processing unit (CPU) 410 to cause computing system 400 to perform operations. In many known computer servers, workstations, personal computers, and the like, CPU 410 is implemented in an integrated circuit called a processor.

It is appreciated that, although exemplary computing system 400 is shown to comprise a single CPU 410, such description is merely illustrative, as computing system 400 may comprise a plurality of CPUs 410. Additionally, computing system 400 may exploit the resources of remote CPUs (not shown), such as other control box units, for example, through communications network 470 or some other data communications means 480.

In operation, CPU 410 fetches, decodes, and executes instructions from a computer readable storage medium such as HDD 415. Such instructions may be included in software such as an operating system (OS), executable programs, and the like, and may include algorithms and applications to perform the functionality described herein.

By way of non-limiting example, CPU 410 may execute, for an island 100 consisting of four control box units 132 and four power units 112, “control box unit 1” may experience high power draw. Accordingly, control box 1 may send a communicative query to “control box 2 unit”, “control box unit 3”, and control box unit 4” requesting additional power. Accordingly, control box units 2, 3 and 4 may report their respective current states, current draw rates, use condition for the past time period, and expected upcoming power needs based on historic trends, by way of example.

In this example, control box units 2 and 4 may report limited availability and a need to “wait” before sharing power. Control box unit 3 may report available power, and may provide the excess power to a localized grid. Control box units 2 and 4 may allow this power to pass through to maximize the power input passed to control box unit 1.

A query/status cycle such as the foregoing may repeat every “X” minutes, and the system may rebalance. Thereby, multiple control box units and/or power units may be enabled to take or contribute power based on the needs of the grid. If no power is available when needed, an alert message may be generated and temporary power may be added, such as through secondary power input 116. Ultimately, even this secondary/temporary power may be redistributed by the control box units to a system, island or workstation of greatest need. Moreover, if no secondary power is available, other control boxes may execute a contribution of available power until the overall system is normalized.

Information, such as computer instructions and other computer readable data, is transferred between components of computing system 400 via the system's main data-transfer path. The main data-transfer path may use a system bus architecture 405, although other computer architectures (not shown) can be used, such as architectures using serializers and deserializers and crossbar switches to communicate data between devices over serial communication paths. System bus 405 may include data lines for sending data, address lines for sending addresses, and control lines for sending interrupts and for operating the system bus. Some busses provide bus arbitration that regulates access to the bus by extension cards, controllers, and CPU 410.

Memory devices coupled to system bus 405 may include random access memory (RAM) 425 and/or read only memory (ROM) 430. Such memories include circuitry that allows information to be stored and retrieved. ROMs 430 generally contain stored data that cannot be modified. Data stored in RAM 425 can be read or changed by CPU 410 or other hardware devices. Access to RAM 425 and/or ROM 430 may be controlled by memory controller 420. Memory controller 420 may provide an address translation function that translates virtual addresses into physical addresses as instructions are executed.

In addition, computing system 400 may contain peripheral communications controller and bus 435, which is responsible for communicating instructions from CPU 410 to, and/or receiving data from, peripherals, such as peripherals 440, 445, and 450, which may include printers, keyboards, and/or the elements discussed herein throughout. An example of a peripheral bus is the Peripheral Component Interconnect (PCI) bus.

Display 460, which is controlled by display controller 455, may be used to display visual output and/or presentation generated by or at the request of computing system 400, responsive to operation of the aforementioned computing program. Such visual output may include text, graphics, animated graphics, and/or video, for example. Display 460 may be implemented with a CRT-based video display, an LCD or LED-based display, a gas plasma-based flat-panel display, a touch-panel display, or the like. Display controller 455 includes electronic components required to generate a video signal that is sent to display 460.

Further, computing system 400 may contain network adapter 465 which may be used to couple computing system 400 to external communication network 470, which may include or provide access to the Internet, an intranet, an extranet, or the like. Communications network 470 may provide user access for computing system 400 with means of communicating and transferring software and information electronically. Additionally, communications network 470 may provide for distributed processing, which involves several computers and the sharing of workloads or cooperative efforts in performing a task. Network adaptor 465 may communicate to and from network 470 using any available wired or wireless technologies. Such technologies may include, by way of non-limiting example, cellular, Wi-Fi, Bluetooth, infrared, or the like.

It is appreciated that exemplary computing system 400 is merely illustrative of a computing environment in which the herein described systems and methods may operate, and does not limit the implementation of the herein described systems and methods in computing environments having differing components and configurations. That is to say, the inventive concepts described herein may be implemented in various computing environments using various components and configurations.

In the foregoing detailed description, it may be that various features are grouped together in individual embodiments for the purpose of brevity in the disclosure. This method of disclosure is not to be interpreted as reflecting an intention that any subsequently claimed embodiments require more features than are expressly recited.

Further, the descriptions of the disclosure are provided to enable any person skilled in the art to make or use the disclosed embodiments. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but rather is to be accorded the widest scope consistent with the principles and novel features disclosed herein.

What is claimed is:

1. A system for providing a smart desk chair, comprising:
a power supply at least partially integrated with a chair frame;
a control box unit associated with the chair frame and which receives power from and is communicative with the power unit, and comprises a power output suitable to output power to features on the chair frame;
the features comprising:
a plurality of strain gauges affixed to portions of the smart desk chair and receiving power from the power supply;
a plurality of comfort and well-being outputs affixed to portions of the smart desk chair and receiving power from the power supply; and
an application wirelessly associated with the plurality of strain gauges and the plurality of comfort and well-being outputs capable of providing user and automated control of, and information related to, use of the smart desk chair and actuation of the comfort and well-being outputs by communicating wirelessly with the plurality of strain gauges and the plurality of comfort and well-being outputs.

2. The system of claim 1, wherein the smart desk chair is a direct current device.

3. The system of claim 1, wherein the control box unit is wired to the power supply.

4. The system of claim 1, wherein the control box unit is wirelessly connected to the power supply.

5. The system of claim 1, wherein the application is on a mobile device.

6. The system of claim 1, further comprising ambient energy collectors on the chair to further charge the power supply.

7. The system of claim 6, wherein one of the ambient energy collectors comprises a thermal energy collector.

8. The system of claim 6, wherein one of the ambient energy collectors comprises a kinetic energy collector.

9. The system of claim 1, wherein the control box unit further comprises a controller suitable to assess power needs of the smart desk chair and the features.

10. The system of claim 9, wherein the controller further controls the power to output either DC or AC power dependent upon the power needs.

11. The system of claim 1, wherein the control box unit further comprises a network connectivity module.

12. The system of claim 11, wherein the network connectivity module comprises a connection to an external mobile device.

13. The system of claim 12, wherein the mobile device connection includes a transmit and receive to and from the application.

14. The system of claim 1, wherein ones of the strain gauges are tri-axial.

15. The system of claim 1, wherein the strain gauges comprise a particular directional sensing array.

16. The system of claim 1, wherein the comfort output comprises heating.

17. The system of claim 16, wherein the heating is only at specified locations on the smart desk chair.

18. The system of claim 1, wherein the comfort output comprises cooling.

19. The system of claim 18, wherein the cooling is only at specified locations on the smart desk chair.
